(19) United States
(12) Patent Application Publication
(10) Pub. No.: US 2025/0286533 A1
(43) Pub. Date: Sep. 11, 2025

(54) ACOUSTIC WAVE DEVICE WITH REDUCED ACOUSTIC LOSS

(71) Applicant: SKYWORKS SOLUTIONS, INC., Irvine, CA (US)

(72) Inventors: Michael David Hill, Emmitsburg, MD (US); Rei Goto, Osaka-Shi (JP)

(21) Appl. No.: 19/069,567

(22) Filed: Mar. 4, 2025

Related U.S. Application Data
(60) Provisional application No. 63/562,103, filed on Mar. 6, 2024.

(51) Int. Cl. H03H 9/145; C22C 9/00; H03H 9/02; H03H 9/25

(52) U.S. Cl. CPC H03H 9/14541; C22C 9/00; H03H 9/02834; H03H 9/02952; H03H 9/25

(57) ABSTRACT

Aspects and embodiments disclosed herein include an acoustic wave device comprising a substrate, interdigital transducer (IDT) electrodes disposed on the substrate and configured to generate an acoustic wave in response to an electrical signal, the IDT electrodes including copper (Cu) and at least one of nickel (Ni) and beryllium (Be), and a passivation layer disposed on the substrate and the IDT electrodes.

### CROSS-REFERENCE TO RELATED APPLICATIONS

This application claims priority under 35 U.S.C. 119(e) to U.S. Provisional Patent Application Ser. No. 63/562,103, titled “ACOUSTIC WAVE DEVICE WITH REDUCED ACOUSTIC LOSS,” filed Mar. 6, 2024, the entire content of which is incorporated herein by reference for all purposes.

### BACKGROUND

### Field

Aspects and embodiments disclosed herein relate to electronic systems, and in particular, to a filter for use in radio frequency (RF) electronics.

### Description of Related Technology

Filters are used in radio frequency (RF) communication systems to allow signals to pass through at discrete frequencies and to reject any frequency outside of the specified range. An acoustic wave filter, which is used widely in the wireless communication field, can include a plurality of resonators arranged to filter a radio frequency signal. Example acoustic wave filters include surface acoustic wave (SAW) filters and/or bulk acoustic wave (BAW) filters. A film bulk acoustic wave resonator filter is an example of a BAW filter. Acoustic wave filters can be implemented in radio frequency electronic systems. For instance, filters in a radio frequency front end of a mobile phone can include acoustic wave filters. A plurality of acoustic wave filters can be arranged as a multiplexer. For example, two surface acoustic wave filters can be arranged as a duplexer.

Examples of RF communication systems with one or more filter modules include, but are not limited to, mobile phones, tablets, base stations, network access points, customer-premises equipment (CPE), laptops, and wearable electronics. For example, in wireless devices that communicate using a cellular standard, a wireless local area network (WLAN) standard, and/or any other suitable communication standard, a power amplifier can be used for RF signal amplification. An RF signal can have a frequency in the range of about 30 kHz to 300 GHz, such as in the range of about 410 MHz to about 7.125 GHz for certain communications standards.

### SUMMARY

In accordance with one aspect, there is provided an acoustic wave device. The acoustic wave device comprises a substrate, interdigital transducer (IDT) electrodes disposed on the substrate and configured to generate an acoustic wave in response to an electrical signal, the IDT electrodes including copper (Cu) and at least one of nickel (Ni) and beryllium (Be), and a passivation layer disposed on the substrate and the IDT electrodes.

In some embodiments, the IDT electrodes are formed of an alloy including copper (Cu) and beryllium (Be).

In some embodiments, an amount of the beryllium (Be) included in the IDT electrode is less than 5% of the IDT electrodes.

In some embodiments, the IDT electrodes are formed of an alloy including copper (Cu) and nickel (Ni).

In some embodiments, the substrate is a multilayer piezoelectric substrate (MPS) including a support substrate and a piezoelectric layer.

In some embodiments, the substrate further includes a dielectric layer.

In some embodiments, the substrate further includes a trap rich layer.

In some embodiments, each of the IDT electrodes includes a lower layer and an upper layer.

In some embodiments, at least one of the lower layer and the upper layer of each of the IDT electrodes includes copper (Cu) and at least one of nickel (Ni) and beryllium (Be).

In some embodiments, the acoustic wave device further includes a dielectric film formed to cover at least a part of the substrate and the IDT electrode.

In accordance with another aspect, there is provided a radio frequency module. The radio frequency module comprises a packaging board configured to receive a plurality of components, and an acoustic wave device implemented on the packaging board, the acoustic wave device including a substrate, interdigital transducer (IDT) electrodes disposed on the substrate and configured to generate an acoustic wave in response to an electrical signal, the IDT electrodes including copper (Cu) and at least one of nickel (Ni) and beryllium (Be), and a passivation layer disposed on the substrate and the IDT electrodes.

In some embodiments, the radio frequency module is a front-end module.

In some embodiments, the IDT electrodes are formed of an alloy including copper (Cu) and beryllium (Be).

In some embodiments, an amount of the beryllium (Be) included in the IDT electrode is less than 5% of the IDT electrodes.

In some embodiments, the IDT electrodes are formed of an alloy including copper (Cu) and nickel (Ni).

In some embodiments, the substrate is a multilayer piezoelectric substrate (MPS) including a support substrate and a piezoelectric layer.

In some embodiments, the substrate further includes a dielectric layer.

In some embodiments, the substrate further includes a trap rich layer.

In some embodiments, each of the IDT electrodes includes a lower layer and an upper layer.

In some embodiments, at least one of the lower layer and the upper layer of each of the IDT electrodes includes copper (Cu) and at least one of nickel (Ni) and beryllium (Be).

In some embodiments, the acoustic wave device further includes a dielectric film formed to cover at least a part of the substrate and the IDT electrode.

In accordance with another aspect, there is provided a mobile device. The mobile device comprises an antenna configured to receive a radio frequency signal, and a front end system configured to communicate with the antenna, the front end system including an acoustic wave device, the acoustic wave device including a substrate, interdigital transducer (IDT) electrodes disposed on the substrate and configured to generate an acoustic wave in response to an electrical signal, the IDT electrodes including copper (Cu) and at least one of nickel (Ni) and beryllium (Be), and a passivation layer disposed on the substrate and the IDT electrodes.

In some embodiments, the IDT electrodes are formed of an alloy including copper (Cu) and beryllium (Be).

In some embodiments, an amount of the beryllium (Be) included in the IDT electrode is less than 5% of the IDT electrodes.

In some embodiments, the IDT electrodes are formed of an alloy including the copper (Cu) and the nickel (Ni).

In some embodiments, the substrate is a multilayer piezoelectric substrate (MPS) including a support substrate and a piezoelectric layer.

In some embodiments, the substrate further includes a dielectric layer.

In some embodiments, the substrate further includes a trap rich layer.

In some embodiments, each of the IDT electrodes includes a lower layer and an upper layer.

In some embodiments, at least one of the lower layer and the upper layer of each of the IDT electrodes includes copper (Cu) and at least one of nickel (Ni) and beryllium (Be).

In some embodiments, the acoustic wave device further includes a dielectric film formed to cover at least a part of the substrate and the IDT electrode.

### BRIEF DESCRIPTION OF THE DRAWINGS

FIG. 1 is a schematic diagram of one embodiment of a mobile device;

FIG. 2A is a schematic diagram of a carrier aggregation system;

FIG. 2B is a schematic diagram of a carrier aggregation system;

FIG. 2C is a schematic diagram of a carrier aggregation system;

FIG. 2D is a schematic diagram of a carrier aggregation system;

FIG. 3A is a schematic block diagram of a module that includes a filter;

FIG. 3B is a schematic block diagram of a module that includes a filter;

FIG. 4 illustrates an example of a schematic diagram of a multilayer piezoelectric substrate (MPS) SAW resonator;

FIG. 5 shows the acoustic loss tangent values of various materials;

FIG. 6 illustrates a schematic diagram of an example of an acoustic wave device according to an embodiment of the present disclosure;

FIG. 7A shows a simulated result of measuring the admittance of the acoustic wave device according to an embodiment of the present disclosure;

FIG. 7B shows a simulated result of measuring the quality factor of the acoustic wave device according to an embodiment of the present disclosure;

FIG. 8 illustrates a schematic diagram of an example of an acoustic wave device according to an embodiment of the present disclosure;

FIG. 9A is a schematic diagram of one embodiment of a packaged module;

FIG. 9B is a schematic diagram of a cross-section of the packaged module of FIG. 9A taken along the lines 9B-9B; and

FIG. 10 is a schematic diagram of one embodiment of a phone board.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

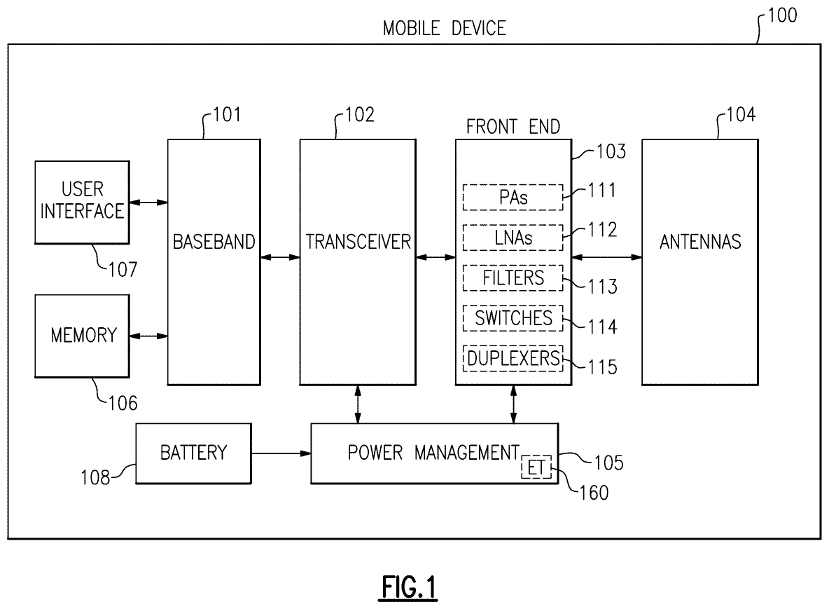

FIG. 1 is a schematic diagram of one example of a mobile device 100. The mobile device 100 includes a baseband system 101, a transceiver 102, a front end system 103, antennas 104, a power management system 105, a memory 106, a user interface 107, and a battery 108.

The mobile device 100 can be used communicate using a wide variety of communications technologies, including, but not limited to, 2G, 3G, 4G (including LTE, LTE-Advanced, and LTE-Advanced Pro), 5G, WLAN (for instance, Wi-Fi), WPAN (for instance, Bluetooth and ZigBee), WMAN (for instance, WiMax), and/or GPS technologies.

The transceiver 102 generates RF signals for transmission and processes incoming RF signals received from the antennas 104. It will be understood that various functionalities associated with the transmission and receiving of RF signals can be achieved by one or more components that are collectively represented in FIG. 1 as the transceiver 102. In one example, separate components (for instance, separate circuits or dies) can be provided for handling certain types of RF signals.

The front end system 103 aids in conditioning signals transmitted to and/or received from the antennas 104. In the illustrated embodiment, the front end system 103 includes power amplifiers (PAS) 111, low noise amplifiers (LNAs) 112, filters 113, switches 114, and duplexers 115. However, other implementations are possible.

For example, the front end system 103 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 100 supports carrier aggregation, thereby providing flexibility to increase peak data rates. Carrier aggregation can be used for both Frequency Division Duplexing (FDD) and Time Division Duplexing (TDD) and may be used to aggregate a plurality of carriers or channels. Carrier aggregation includes contiguous aggregation, in which contiguous carriers within the same operating frequency band are aggregated. Carrier aggregation can also be non-contiguous and can include carriers separated in frequency within a common band and/or in different bands.

The antennas 104 can include antennas used for a wide variety of types of communications. For example, the antennas 104 can include antennas used for transmitting and/or receiving signals associated with a wide variety of frequencies and communications standards.

In certain implementations, the antennas 104 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 100 can operate with beamforming in certain implementations. For example, the front end system 103 can include phase shifters having variable phase controlled by the transceiver 102. Additionally, the phase shifters are controlled to provide beam formation and directivity for transmission and/or reception of signals using the antennas 104. For example, in the context of signal transmission, the phases of the transmit signals provided to the antennas 104 are controlled such that radiated signals from the antennas 104 combine using constructive and destructive interference to generate an aggregate transmit signal exhibiting beam-like qualities with more signal strength propagating in a given direction. In the context of signal reception, the phases are controlled such that more signal energy is received when the signal is arriving to the antennas 104 from a particular direction. In certain implementations, the antennas 104 include one or more arrays of antenna elements to enhance beamforming.

The baseband system 101 is coupled to the user interface 107 to facilitate processing of various user input and output (I/O), such as voice and data. The baseband system 101 provides the transceiver 102 with digital representations of transmit signals, which the transceiver 102 processes to generate RF signals for transmission. The baseband system 101 also processes digital representations of received signals provided by the transceiver 102. As shown in FIG. 1, the baseband system 101 is coupled to the memory 106 to facilitate operation of the mobile device 100.

The memory 106 can be used for a wide variety of purposes, such as storing data and/or instructions to facilitate the operation of the mobile device 100 and/or to provide storage of user information.

The power management system 105 provides a number of power management functions of the mobile device 100. The power management system 105 of FIG. 1 includes an envelope tracker 160. As shown in FIG. 1, the power management system 105 receives a battery voltage from the battery 108. The battery 108 can be any suitable battery for use in the mobile device 100, including, for example, a lithium-ion battery.

The mobile device 100 of FIG. 1 illustrates one example of an RF communication system that can include power amplifier(s) implemented in accordance with one or more features of the present disclosure. However, the teachings herein are applicable to RF communication systems implemented in a wide variety of ways.

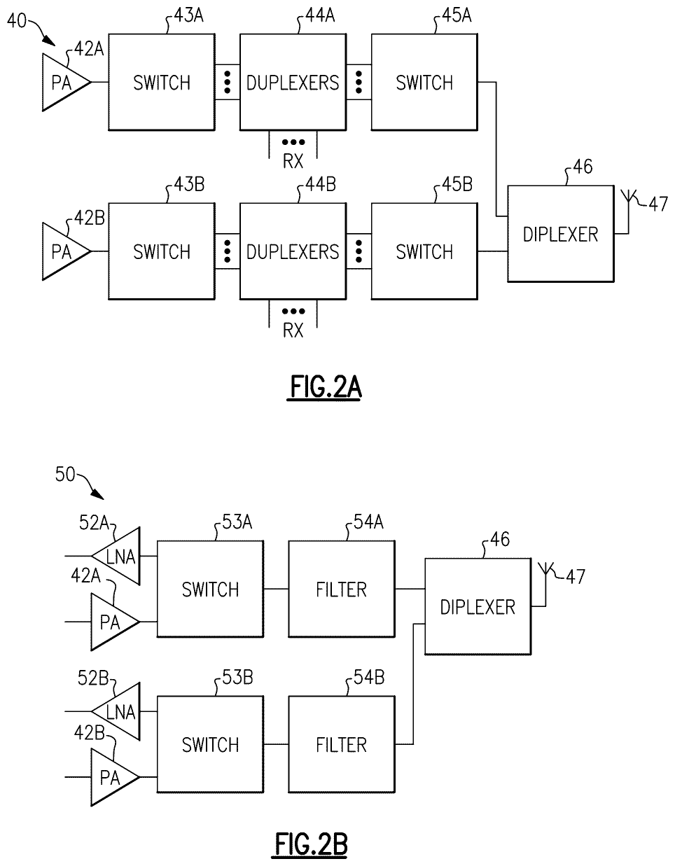

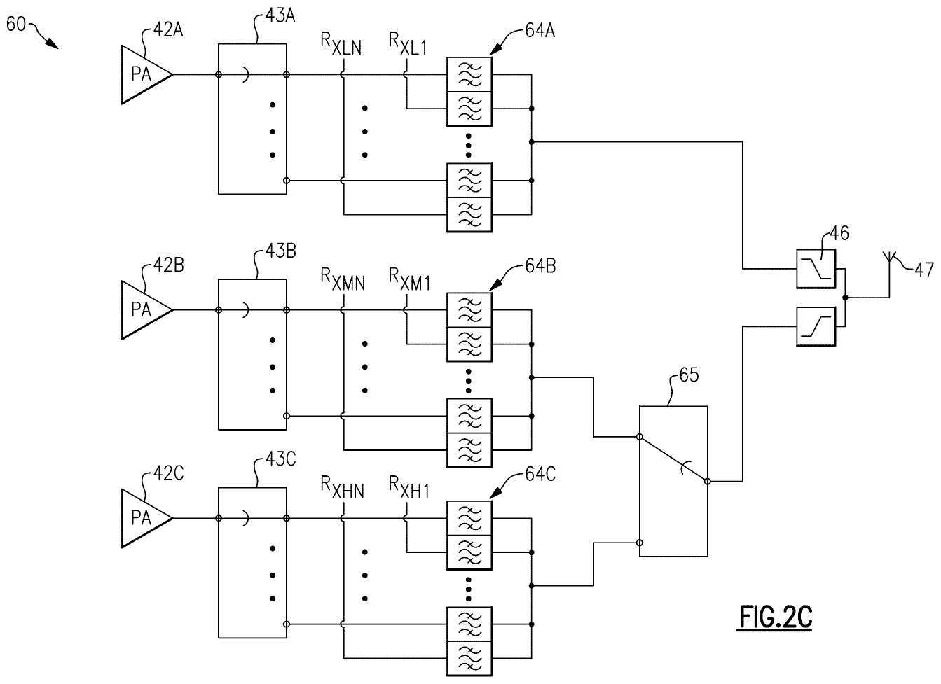

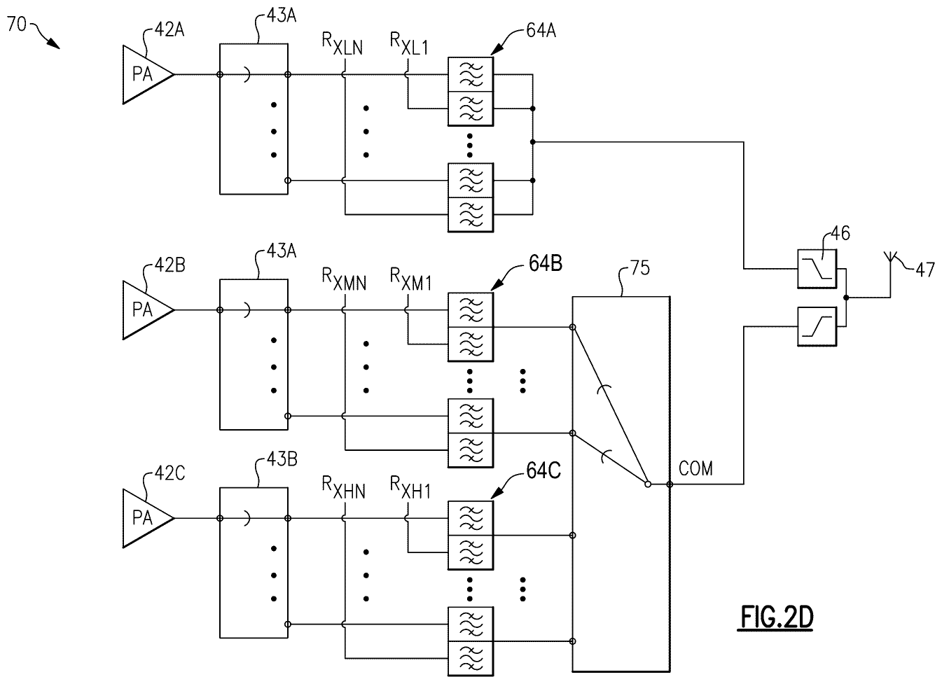

FIG. 2A is a schematic diagram of a carrier aggregation system 40. The illustrated carrier aggregation system 40 includes power amplifiers 42A and 42B, switches 43A and 43B, duplexers 44A and 44B, switches 45A and 45B, diplexer 46, and antenna 47. The power amplifiers 42A and 42B can each transmit an amplified RF signal associated with a different carrier. The switch 43A can be a band select switch. The switch 43A can couple an output of the power amplifier 42A to a selected duplexer of the duplexers 44A. Each of the duplexers can include a transmit filter and a receive filter. Any of the filters of the duplexers 44A and 44B can be implemented in accordance with any suitable principles and advantages discussed herein. The switch 45A can couple the selected duplexer of the duplexers 44A to the diplexer 46. The diplexer 46 can combine RF signals provided by the switches 45A and 45B into a carrier aggregation signal that is transmitted by the antenna 47. The diplexer 46 can isolate different frequency bands of a carrier aggregation signal received by the antenna 47. The diplexers 46 is an example of a frequency domain multiplexer. Other frequency domain multiplexers include a triplexer. Carrier aggregation systems that include triplexers can process carrier aggregation signals associated with three carriers. The switches 45A and 45B and selected receive filters of the duplexers 44A and 44B can provide RF signals with the isolated frequency bands to respective receive paths.

FIG. 2B is a schematic diagram of a carrier aggregation system 50. The illustrated carrier aggregation system 50 includes power amplifiers 42A and 42B, low noise amplifiers 52A and 52B, switches 53A and 53B, filters 54A and 54B, diplexer 46, and antenna 47. The power amplifiers 42A and 42B can each transmit an amplified RF signal associated with a different carrier. The switch 53A can be a transmit/receive switch. The switch 53A can couple the filter 54A to an output of the power amplifier 42A in a transmit mode and to an input of the low noise amplifier 52A in a receive mode. The filter 54A and/or the filter 54B can be implemented in accordance with any suitable principles and advantages discussed herein. The diplexer 46 can combine RF signals from the power amplifiers 42A and 42B provided by the switches 53A and 53B into a carrier aggregation signal that is transmitted by the antenna 47. The diplexer 46 can isolate different frequency bands of a carrier aggregation signal received by the antenna 47. The switches 53A and 53B and the filters 54A and 54B can provide RF signals with the isolated frequency bands to respective low noise amplifiers 52A and 52B.

FIG. 2C is a schematic diagram of a carrier aggregation system 60 that includes multiplexers in signal paths between power amplifiers and an antenna. The illustrated carrier aggregation system 60 includes a low band path, a medium band path, and a high band path. In certain implementations, a low band path can process radio frequency signals having a frequency of less than 1 GHZ, a medium band path can process radio frequency signals having a frequency between 1 GHz and 2.2 GHZ, and a high band path can process radio frequency signals having a frequency above 2.2 GHZ.

A diplexer 46 can be included between RF signal paths and an antenna 47. The diplexer 46 can frequency multiplex radio frequency signals that are relatively far away in frequency. The diplexer 46 can be implemented with passive circuit elements having a relatively low loss. The diplexer 46 can combine (for transmit) and separate (for receive) carriers of carrier aggregation signals.

As illustrated, the low band path includes a power amplifier 42A configured to amplify a low band radio frequency signal, a band select switch 43A, and a multiplexer 64A. The band select switch 43A can electrically connect the output of the power amplifier 42A to a selected transmit filter of the multiplexer 64A. The selected transmit filter can be a band pass filter with pass band corresponding to a frequency of an output signal of the power amplifier 42A. The multiplexer 64A can include any suitable number of transmit filters and any suitable number of receive filters. One or more of the transmit filters and/or one or more of the receive filters can be implemented in accordance with any suitable principles and advantages discussed herein. The multiplexer 64A can have the same number of transmit filters as receive filters. In some instances, the multiplexer 64A can have a different number of transmit filters than receive filters.

As illustrated in FIG. 2C, the medium band path includes a power amplifier 42B configured to amplify a medium band radio frequency signal, a band select switch 43B, and a multiplexer 64B. The band select switch 43B can electrically connect the output of the power amplifier 42B to a selected transmit filter of the multiplexer 64B. The selected transmit filter can be a band pass filter with pass band corresponding to a frequency of an output signal of the power amplifier 42B. The multiplexer 64B can include any suitable number of transmit filters and any suitable number of receive filters. One or more of the transmit filters and/or one or more of the receive filters can be implemented in accordance with any suitable principles and advantages discussed herein. The multiplexer 64B can have the same number of transmit filters as receive filters. In some instances, the multiplexer 64B can have a different number of transmit filters than receive filters.

In the illustrated carrier aggregation system 60, the high band path includes a power amplifier 42C configured to amplify a high band radio frequency signal, a band select switch 43C, and a multiplexer 64C. The band select switch 43C can electrically connect the output of the power amplifier 42C to a selected transmit filter of the multiplexer 64C. The selected transmit filter can be a band pass filter with pass band corresponding to a frequency of an output signal of the power amplifier 42C. The multiplexer 64C can include any suitable number of transmit filters and any suitable number of receive filters. One or more of the transmit filters and/or one or more of the receive filters can be implemented in accordance with any suitable principles and advantages discussed herein. The multiplexer 64C can have the same number of transmit filters as receive filters. In some instances, the multiplexer 64C can have a different number of transmit filters than receive filters.

A select switch 65 can selectively provide a radio frequency signal from the medium band path or the high band path to the diplexer 46. Accordingly, the carrier aggregation system 60 can process carrier aggregation signals with either a low band and high band combination or a low band and medium band combination.

FIG. 2D is a schematic diagram of a carrier aggregation system 70 that includes multiplexers in signal paths between power amplifiers and an antenna. The carrier aggregation system 70 is like the carrier aggregation system 60 of FIG. 2C, except that the carrier aggregation system 70 includes switch-plexing features. Switch-plexing can be implemented in accordance with any suitable principles and advantages discussed herein.

Switch-plexing can implement on-demand multiplexing. Some radio frequency systems can operate in a single carrier mode for a majority of time (e.g., about 95% of the time) and in a carrier aggregation mode for a minority of the time (e.g., about 5% of the time). Switch-plexing can reduce loading in a single carrier mode in which the radio frequency system can operate for the majority of the time relative to a multiplexer that includes filters having a fixed connection at a common node. Such a reduction in loading can be more significant when there are a relatively larger number of filters included in multiplexer.

In the illustrated carrier aggregation system 70, duplexers 64B and 64C are selectively coupled to a diplexer 46 by way of a switch 75. The switch 75 is configured as a multi-close switch that can have two or more throws active concurrently. Having multiple throws of the switch 75 active concurrently can enable transmission and/or reception of carrier aggregation signals. The switch 75 can also have a single throw active during a single carrier mode. As illustrated, each duplexer of the duplexers 64B is coupled to separate throws of the switch 75. Similarly, the illustrated duplexers 64C include a plurality of duplexers coupled to separate throws of the switch 75. Alternatively, instead of duplexers being coupled to each throw the switch 75 as illustrated in FIG. 2D, one or more individual filters of a multiplexer can be coupled to a dedicated throw of a switch coupled between the multiplexer and a common node. For instance, in some implementations, such a switch could have twice as many throws as the illustrated switch 75.

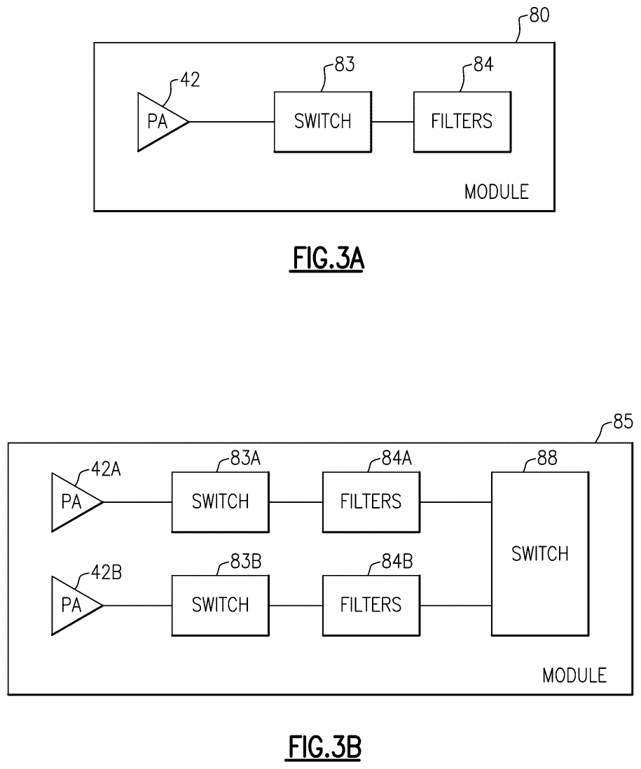

The filters discussed herein can be implemented in a variety of packaged modules. Some example packaged modules will now be discussed in which any suitable principles and advantages of the filters discussed herein can be implemented. FIGS. 3A and 3B are schematic block diagrams of illustrative packaged modules according to certain embodiments.

FIG. 3A is a schematic block diagram of a module 80 that includes a power amplifier 42, a switch 83, and filters 84 in accordance with one or more embodiments. The module 80 can include a package that encloses the illustrated elements. The power amplifier 42, a switch 83, and filters 84 can be disposed on the same packaging substrate. The packaging substrate can be a laminate substrate, for example. The switch 83 can be a multi-throw radio frequency switch. The switch 83 can electrically couple an output of the power amplifier 42 to a selected filter of the filters 84. The filters 84 can include any suitable number of surface acoustic wave filters. One or more filters of the filters 84 can be implemented in accordance with any suitable principles and advantages disclosed herein.

FIG. 3B is a schematic block diagram of a module 85 that includes power amplifiers 42A and 42B, switches 83A and 83B, and filters 84A and 84B in accordance with one or more embodiments, and an antenna switch 88. The module 85 is like the module 80 of FIG. 3A, except the module 85 includes an additional RF signal path and the antenna switch 88 arranged to selectively couple a signal from the filters 84A or the filters 84B to an antenna node. One or more filters of the filters 84A and/or 84B can be implemented in accordance with any suitable principles and advantages disclosed herein. The additional RF signal path includes an additional power amplifier 42B, an additional switch 83B, and additional filters 84B. The different RF signal paths can be associated with different frequency bands and/or different modes of operation (e.g., different power modes, different signaling modes, etc.).

As discussed above, communications devices, such as mobile phones and the like, use filters and sub-systems incorporating filters (such as duplexers, diplexers, and the like) to separate signals in different frequency bands, such as transmission and reception signals, for example.

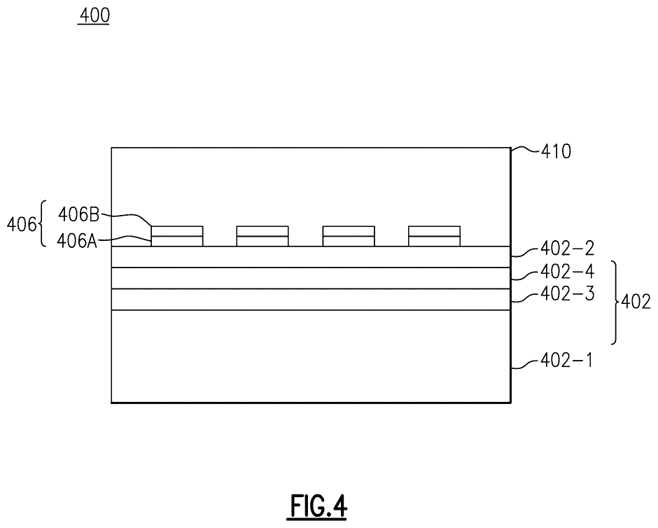

FIG. 4 illustrates an example of a schematic diagram of a multilayer piezoelectric substrate (MPS) SAW resonator 400. The MPS SAW resonator 400 can be included in the MPS filters. The MPS filters can include any suitable number of MPS SAW resonators, such as the MPS SAW resonator 400. The illustrated MPS SAW resonator 400 may include a substrate 402, and IDT electrodes 406. According to an embodiment, optionally, the MPS SAW resonator 400 may further include the dielectric film 410.

The substrate 402 may include a support substrate 402-1 and a piezoelectric layer 402-2. The support substrate 402-1 can be a silicon substrate, a quartz substrate, a SiC-sapphire substrate, a polycrystalline spinel substrate, or any other suitable carrier substrate.

The piezoelectric layer 402-2 may be formed of a lithium niobate (LN) or a lithium tantalate (LT). In certain instances, the piezoelectric layer 402-2 can have a thickness of less than λ, in which λ is a wavelength of a surface acoustic wave generated by the MPS SAW resonator 400.

In some instances, one or more additional layers can be included in the multilayer piezoelectric substrate 402. Non-limiting examples of a layer of the one or more additional layers include a silicon dioxide layer, a silicon nitride layer, an aluminum nitride layer, an adhesion layer, a dispersion adjustment layer, and a thermal dissipation layer.

As an illustrative example, a multilayer piezoelectric substrate 402 may further include a trap-rich layer 402-3 and a dielectric layer 402-4. The trap-rich layer 402-3 may be formed of polycrystalline silicon (Poly-Si), and the dielectric layer 402-4 may be formed of silicon dioxide (SiO₂).

The IDT electrodes 406 may be disposed on the substrate 402 and configured to generate an acoustic wave in response to an electrical signal. The IDT electrodes 406 may include a lower layer 406A and an upper layer 406B. The lower layer 406 is formed of at least one of molybdenum (Mo), tungsten (W), and platinum (Pt). The upper layer 406B is formed of at least one of aluminum (Al), copper (Cu), silver (Ag), and gold (Au).

The dielectric film 410 may optionally be further included in the MPS SAW resonator 400. The dielectric film 410 may be formed to cover at least a part of the substrate 402 and the IDT electrode 406. The dielectric film 410 may be formed of silicon dioxide (SiO₂).

The acoustic loss tangent is defined by the ratio of the elastic energy dissipated to the elastic energy transmitted by a sound wave. The Elastic modulus is represented by a complex number with a real and imaginary part, analogous to the dielectric loss tangent for electrical energy. This acoustic loss is the imaginary part of the complex number (energy dissipated or absorbed) divided by the real part of the elastic modulus (energy transmitted). For the operation of acoustic wave devices, it is desirable to have this acoustic loss tangent to have as low a value as possible. The acoustic loss tangent is inversely related to the quality factor (Q) of the resonator and the performance of the filter composed of such resonators.

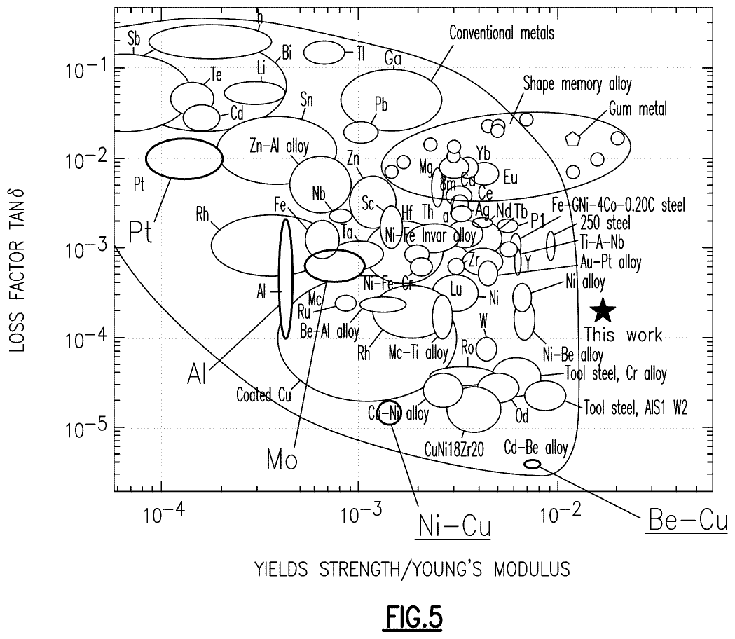

FIG. 5 shows the acoustic loss tangent values of various example materials.

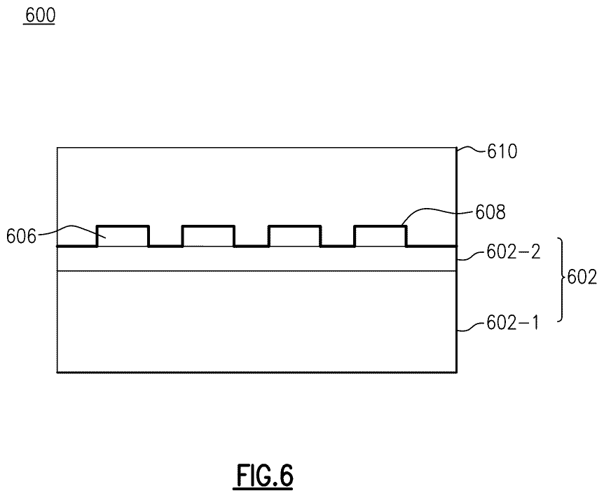

FIG. 6 illustrates a schematic diagram of an example of an acoustic wave device or an acoustic wave resonator according to an embodiment of the present disclosure. The filters described herein may include at least one of the acoustic wave device according to an embodiment of the present disclosure. As shown in FIG. 6, the acoustic wave device 600 may include a substrate 602 and IDT electrodes 606. The acoustic wave device 600 may be an MPS resonator. The acoustic wave device 600 may further include a passivation layer 608. According to an embodiment, the acoustic wave device 600 may optionally include a dielectric film 610.

The substrate 602 may be a multilayer piezoelectric substrate (MPS). The substrate 602 may include a support substrate 602-1 and a piezoelectric layer 602-2. The support substrate 602-1 can be a silicon substrate, a quartz substrate, a SiC-sapphire substrate, a polycrystalline spinel substrate, or any other suitable carrier substrate. According to an embodiment, a SiC-sapphire substrate reduces electrical activity in silicon, contributes to an improved Q, and improves non-linear performance. In addition, a quartz substrate reduces electrical activity in silicon and mechanical loss which will both contribute to improved Q and improved non-liner performance. The unique quartz TCF properties give rise to an improved TCF of the MPS resonator overall.

The piezoelectric layer 602-2 may be formed of lithium niobate (LN) or lithium tantalate (LT). In certain implementations, the substrate 602 may further include a trap-rich layer and a dielectric layer (not shown). The trap-rich layer may be formed of polycrystalline silicon (Poly-Si), and the dielectric layer may be formed of silicon dioxide (SiO₂).

The IDT electrode 606 may be disposed on the substrate 602 and configured to generate an acoustic wave in response to an electrical signal. According to an embodiment, the IDT electrodes may include copper (Cu) and at least one of nickel (Ni) and beryllium (Be). For example, the IDT electrodes may be formed of an alloy including Cu and Ni. Alternatively, the IDT electrodes may be formed of an alloy including Cu and Be.

The material used for the IDT electrodes according to an embodiment provides low acoustic loss, and the low acoustic loss combined with the MPS gives a high Q resonator. For example, the alloy including Cu and Be has a density of 8.25 g/cc and can be heat-treated to achieve resistivity values at 20° C. of 5μΩ/cm to 10 μΩ/cm. Electrodes formed of such a material have only a fraction, for example about 1/10 or about 1/100, of the loss factor tangent as compared to a conventional Al—Mo electrode. According to an embodiment, an amount of Be and/or Ni included in the alloy used for the IDT electrodes may be less than 2% of the total mass of the IDT electrode.

The acoustic wave device 600 may further include a passivation layer 608 disposed on the substrate 602 and the IDT electrode 606. The passivation layer 608 may be formed of at least one of silicon dioxide (SiO₂), silicon nitride (SiN), and silicon oxynitride (SiON). The passivation layer 608 may cover the upper and side surface of the IDT electrodes 606 and the upper surface of the substrate 602. The passivation layer 608 is introduced to protect the IDT electrodes 606 from external damage, for example, chemical reactions, moisture, and similar external influence.

A dielectric film 610 may be formed to cover at least a part of the substrate 602 and the IDT electrode 606. The dielectric film 610 may be implemented as a temperature compensation layer which can bring the temperature coefficient of frequency of the acoustic wave device 600 closer to zero. As an example, a silicon dioxide layer can implement a temperature compensation layer. According to an embodiment, the dielectric film 610 may be replaced with the passivation film 608.

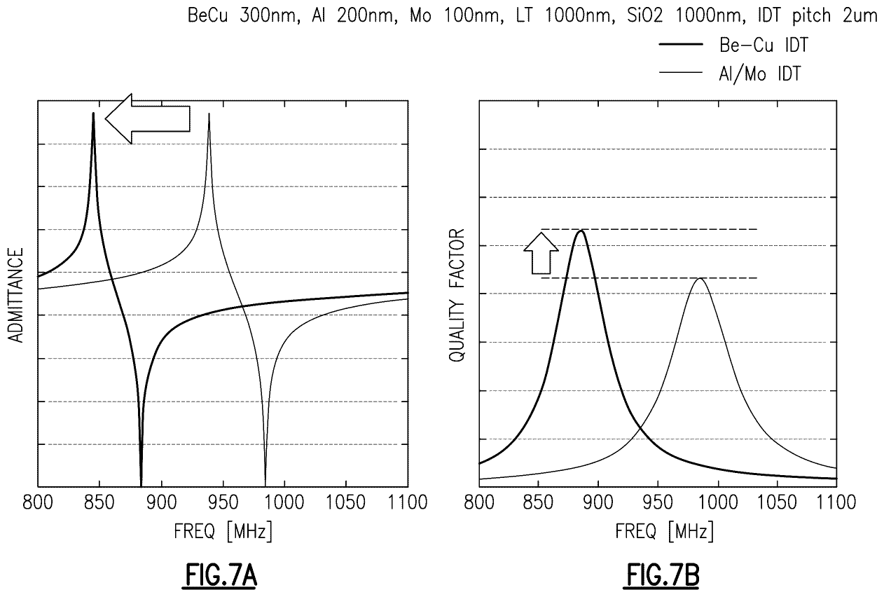

FIG. 7A shows a simulated result of measuring the admittance of the acoustic wave device according to an embodiment of the present disclosure. As shown in FIG. 7A, using Be—Cu for the IDT electrodes provides lower velocity (freq*λ) as compared to conventional materials (in this example, an Al—Mo IDT electrode). The low velocity property achieved by the Be—Cu IDT electrode contributes to reduction in the size of filters formed from such acoustic wave devices.

FIG. 7B shows a simulated result of measuring the quality factor (Q) of the acoustic wave device according to an embodiment of the present disclosure. As shown in FIG. 7B, using Be—Cu for the IDT electrodes provides improved Q by achieving reduced acoustic loss in the IDT electrodes.

FIG. 8 illustrates a schematic diagram of an example of an acoustic wave device or an acoustic wave resonator 800 according to an embodiment of the present disclosure. In this embodiment, each of the IDT electrodes 606 may include a lower layer 606A and an upper layer 606B. The rest of the features of the acoustic wave device 800 shown in FIG. 8 is analogous to those of the acoustic wave device 600 shown in FIG. 6. According to an embodiment, at least one of the lower layer 606A and the upper layer 606B of the IDT electrodes 606 includes copper (Cu) and at least one of nickel (Ni) and beryllium (Be).

For example, the lower layer 606A of the IDT electrodes 606 may be formed of an alloy including Cu and Be. Alternatively, the lower layer 606A of the IDT electrodes 606 may be formed of an alloy including Cu and Ni. In this example, the upper layer 606B of the IDT electrodes 606 may be a high conductivity metal, such as Al or Ag. According to this example, Be—Cu combined with a high conductivity metal contributes to improved Q by lowering resistive loss.

In another example, the upper layer 606B of the IDT electrodes 606 may be formed of an alloy including Cu and Be. Alternatively, the upper layer 606B of the IDT electrodes 606 may be formed of an alloy including Cu and Ni. In this example, the lower layer 606A of the IDT electrodes 606 may be a high density metal, such as W, Pt, Mo, or Ru. According to this example, Be—Cu combined with a high density metal contributes to low velocity acoustic waves which may enable size reduction of a filter.

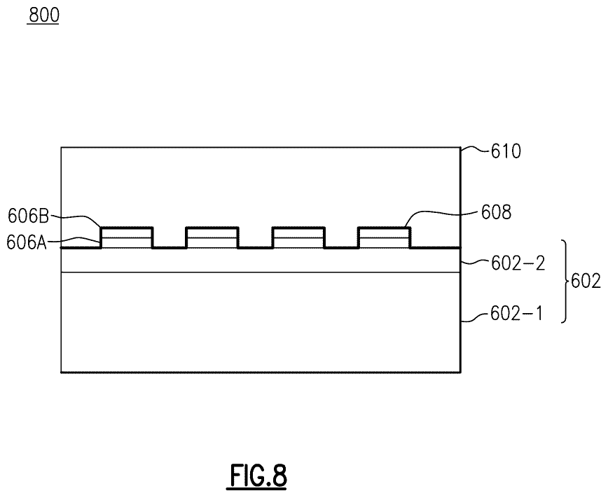

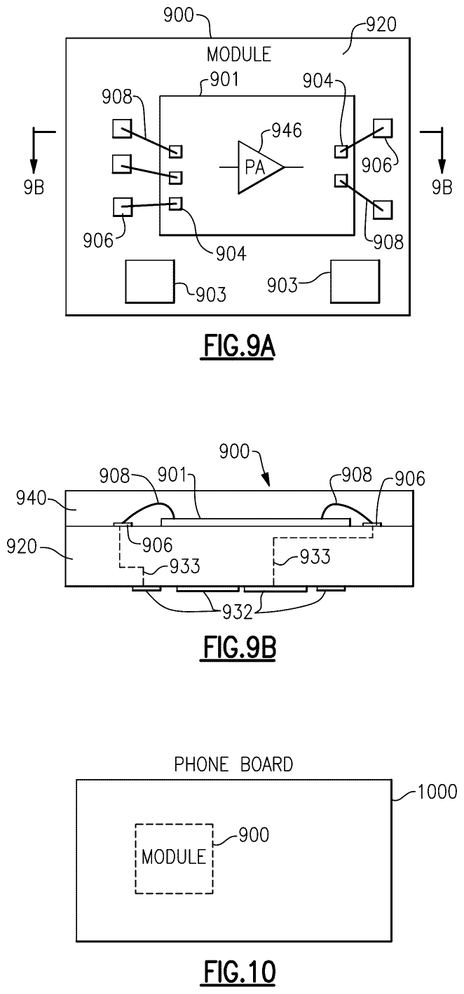

FIG. 9A is a schematic diagram of one embodiment of a packaged module 900. FIG. 9B is a schematic diagram of a cross-section of the packaged module 900 of FIG. 9A taken along the lines 9B-9B.

The packaged module 900 includes an IC or die 901, surface mount components 903, wirebonds 908, a package substrate 920, and encapsulation structure 940. The package substrate 920 includes pads 906 formed from conductors disposed therein. Additionally, the die 901 includes pads 904, and the wirebonds 908 have been used to electrically connect the pads 904 of the die 901 to the pads 906 of the package substrate 920.

The die 901 includes a filter module, which can be implemented in accordance with any of the embodiments herein.

The packaging substrate 920 can be configured to receive a plurality of components such as the die 901 and the surface mount components 903, which can include, for example, surface mount capacitors and/or inductors.

As shown in FIG. 9B, the packaged module 900 is shown to include a plurality of contact pads 932 disposed on the side of the packaged module 900 opposite the side used to mount the die 901. Configuring the packaged module 900 in this manner can aid in connecting the packaged module 900 to a circuit board such as a phone board of a wireless device. The example contact pads 932 can be configured to provide RF signals, bias signals, power low voltage(s) and/or power high voltage(s) to the die 901 and/or the surface mount components 903. As shown in FIG. 9B, the electrical connections between the contact pads 932 and the die 901 can be facilitated by connections 933 through the package substrate 920. The connections 933 can represent electrical paths formed through the package substrate 920, such as connections associated with vias and conductors of a multilayer laminated package substrate.

In some embodiments, the packaged module 900 can also include one or more packaging structures to, for example, provide protection and/or facilitate handling of the packaged module 900. Such a packaging structure can include overmold or encapsulation structure 940 formed over the packaging substrate 920 and the components and die(s) disposed thereon.

It will be understood that although the packaged module 900 is described in the context of electrical connections based on wirebonds, one or more features of the present disclosure can also be implemented in other packaging configurations, including, for example, flip-chip configurations.

FIG. 10 is a schematic diagram of one embodiment of a phone board 1000. The phone board 1000 includes the module 900 shown in FIGS. 9A-9B attached thereto. Although not illustrated in FIG. 10 for clarity, the phone board 1000 can include additional components and structures.

### Applications

Some of the embodiments described above have provided examples in connection with wireless devices or mobile phones. However, the principles and advantages of the embodiments can be used for any other systems or apparatus that have needs for filters.

Such filters can be implemented in various electronic devices. Examples of the electronic devices can include, but are not limited to, consumer electronic products, parts of the consumer electronic products, electronic test equipment, etc. Examples of the electronic devices can also include, but are not limited to, memory chips, memory modules, circuits of optical networks or other communication networks, and disk driver circuits. The consumer electronic products can include, but are not limited to, a mobile phone, a telephone, a television, a computer monitor, a computer, a hand-held computer, a personal digital assistant (PDA), a microwave, a refrigerator, an automobile, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. An acoustic wave device comprising:
a substrate;
interdigital transducer (IDT) electrodes disposed on the substrate and configured to generate an acoustic wave in response to an electrical signal, the IDT electrodes including copper (Cu) and at least one of nickel (Ni) and beryllium (Be); and
a passivation layer disposed on the substrate and the IDT electrodes.

2. The acoustic wave device of claim 1 wherein the IDT electrodes are formed of an alloy including copper (Cu) and beryllium (Be).

3. The acoustic wave device of claim 2 wherein an amount of the beryllium (Be) included in the IDT electrode is less than 5% of the IDT electrodes.

4. The acoustic wave device of claim 1 wherein the IDT electrodes are formed of an alloy including copper (Cu) and nickel (Ni).

5. The acoustic wave device of claim 1 wherein the substrate is a multilayer piezoelectric substrate (MPS) including a support substrate and a piezoelectric layer.

6. The acoustic wave device of claim 5 wherein the substrate further includes a dielectric layer.

7. The acoustic wave device of claim 5 wherein the substrate further includes a trap rich layer.

8. The acoustic wave device of claim 1 wherein each of the IDT electrodes includes a lower layer and an upper layer.

9. The acoustic wave device of claim 8 wherein at least one of the lower layer and the upper layer of each of the IDT electrodes includes copper (Cu) and at least one of nickel (Ni) and beryllium (Be).

10. The acoustic wave device of claim 1 wherein the acoustic wave device further includes a dielectric film formed to cover at least a part of the substrate and the IDT electrode.

11. A radio frequency module comprising:
a packaging board configured to receive a plurality of components; and
an acoustic wave device implemented on the packaging board, the acoustic wave device including a substrate, interdigital transducer (IDT) electrodes disposed on the substrate and configured to generate an acoustic wave in response to an electrical signal, the IDT electrodes including copper (Cu) and at least one of nickel (Ni) and beryllium (Be), and a passivation layer disposed on the substrate and the IDT electrodes.

12. The radio frequency module of claim 11 wherein the radio frequency module is a front-end module.

13. The radio frequency module of claim 11 wherein the IDT electrodes are formed of an alloy including copper (Cu) and beryllium (Be).

14. The radio frequency module of claim 13 wherein an amount of the beryllium (Be) included in the IDT electrode is less than 5% of the IDT electrodes.

15. The radio frequency module of claim 11 wherein the IDT electrodes are formed of an alloy including copper (Cu) and nickel (Ni).

16. The radio frequency module of claim 11 wherein the substrate is a multilayer piezoelectric substrate (MPS) including a support substrate and a piezoelectric layer.

17. The radio frequency module of claim 16 wherein the substrate further includes a dielectric layer.

18. The radio frequency module of claim 16 wherein the substrate further includes a trap rich layer.

19. The radio frequency module of claim 11 wherein each of the IDT electrodes includes a lower layer and an upper layer.

20. A mobile device comprising:
an antenna configured to receive a radio frequency signal; and
a front end system configured to communicate with the antenna, the front end system including an acoustic wave device, the acoustic wave device including a substrate, interdigital transducer (IDT) electrodes disposed on the substrate and configured to generate an acoustic wave in response to an electrical signal, the IDT electrodes including copper (Cu) and at least one of nickel (Ni) and beryllium (Be), and a passivation layer disposed on the substrate and the IDT electrodes.
